(19) United States
(12) Patent Application Publication
(10) Pub. No.: US 2025/0227924 A1
(43) Pub. Date: Jul. 10, 2025

(54) INTEGRATED CIRCUIT DEVICE

(71) Applicant: Samsung Electronics Co., Ltd., Suwon-si (KR)

(72) Inventors: Geun PARK, Suwon-si (KR); Hyukwoo KWON, Suwon-si (KR); Munjun KIM, Suwon-si (KR); Iksoo KIM, Suwon-si (KR); Junwon LEE, Suwon-si (KR); Kwanghee CHEON, Suwon-si (KR); Younseok CHOI, Suwon-si (KR)

(73) Assignee: Samsung Electronics Co., Ltd., Suwon-si, Gyeonggi-do (KR)

(21) Appl. No.: 18/752,950

(22) Filed: Jun. 25, 2024

(30) Foreign Application Priority Data
Jan. 4, 2024 (KR) 10-2024-0001673

(51) Int. Cl. H10B 12/00

(52) U.S. Cl. CPC H10B 12/50; H10B 12/09; H10B 12/315

(57) ABSTRACT

An integrated circuit may include a substrate comprising a cell array area and a peripheral area, a plurality of lower electrodes in the cell array area, at least one supporter contacting the plurality of lower electrodes, a dielectric film covering the plurality of lower electrodes and the at least one supporter layer, an upper electrode covering the dielectric film, a plate layer surrounding a top surface and a side surface of the upper electrode, an oxide layer contacting a top surface of the plate layer, and a peripheral contact plug passing through an interlayer insulating layer and in the peripheral area of the substrate. The upper electrode comprises at least one protruding areas protruding in a lateral direction, and the integrated circuit device defines an air gap conformally surrounding the at least one protruding area of the upper electrode in the lateral direction.

### CROSS-REFERENCE TO RELATED APPLICATION

This application is based on and claims priority under 35 U.S.C. § 119 to Korean Patent Application No. 10-2024-0001673, filed on Jan. 4, 2024, in the Korean Intellectual Property Office, the disclosure of which is incorporated by reference herein in its entirety.

### BACKGROUND

Various example embodiments relate to an integrated circuit device. More particularly, various example embodiments relate to an integrated circuit device including a memory unit such as a capacitor.

Recently, as high-integration of integrated circuit devices has been accelerated due to the rapid development of small-sized semiconductor process technology, the area of a unit cell has decreased. Accordingly, the area that a memory unit such as a capacitor may occupy within the unit cell has also decreased. For example, as the integration level of an integrated circuit device such as a dynamic random-access memory (DRAM) has increased, the area of a unit cell has decreased while the required capacitance has been maintained or increased. Accordingly, there is a need for or a desire for a structure that may overcome spatial limitations and design rule limitations in capacitors, improve capacitance, and/or maintain desired electrical characteristics.

### SUMMARY

Various inventive concepts provide an integrated circuit device that may improve electrical characteristics and/or product reliability.

Technical problems to be solved by or improved upon by inventive concepts are not limited to the above-described technical problems, and one of ordinary skill in the art will understand other technical problems from the following description.

According to various example embodiments, there is provided an integrated circuit device.

The integrated circuit device includes a substrate including a cell array area and a peripheral area, a plurality of lower electrodes in the cell array area, at least one supporter layer contacting the plurality of lower electrodes and extending in a first direction parallel to a top surface of the substrate, a dielectric film covering the plurality of lower electrodes and the at least one supporter layer, an upper electrode covering the dielectric film, a plate layer surrounding a top surface and a side surface of the upper electrode, an oxide layer contacting a top surface of the plate layer and extending in a second direction parallel to the substrate, an interlayer insulating layer covering a top surface of the oxide layer and the side surface of the upper electrode, and a peripheral contact plug passing through the interlayer insulating layer located in the peripheral area of the substrate. The upper electrode includes at least one protruding areas protruding in a lateral direction. The lateral direction is a horizontal direction from the cell array area toward the peripheral area. The integrated circuit device defines an air gap conformally surrounding the at least one protruding area of the upper electrode in the lateral direction.

Alternatively or additionally according to various example embodiments, an integrated circuit device includes a substrate including a cell array area and a peripheral area, a capacitor structure including a plurality of lower electrodes in the cell array area, a dielectric film on the plurality of lower electrodes, and an upper electrode covering the dielectric film, a plate layer covering a side surface and a top surface of the capacitor structure, and an interlayer insulating layer covering a top surface and a side surface of the plate layer. The integrated circuit device defines an air gap between the side surface of the plate layer and the interlayer insulating layer.

Alternatively or additionally according to various example embodiments, an integrated circuit device includes a substrate including a memory cell area and a peripheral circuit area around the memory cell area, a plurality of cell transistors located in the memory cell area, a peripheral circuit transistor in the peripheral circuit area, a capacitor structure including lower electrodes on the plurality of cell transistors, a dielectric film on surfaces of the lower electrodes, and an upper electrode located on the dielectric film, a plate structure covering the capacitor structure, an oxide layer contacting a top surface of the plate structure and conformally extending in a direction parallel to the substrate, a first interlayer insulating film between the peripheral circuit transistor in the peripheral circuit area and the oxide layer and the plate structure in the memory cell area, a second interlayer insulating film on the oxide layer and covering the oxide layer, an upper electrode contact plug passing through a part of the upper electrode located in the memory cell area and electrically connected to the upper electrode, a peripheral contact sequentially passing through the second interlayer insulating film, the oxide layer, and the first interlayer insulating film in the peripheral circuit area, and an air gap located between the first interlayer insulating film and the plate structure and conformally extending on a side surface of the plate structure.

### BRIEF DESCRIPTION OF THE DRAWINGS

Various example embodiments will be more clearly understood from the following detailed description taken in conjunction with the accompanying drawings in which:

FIG. 1 is a schematic plan view illustrating an integrated circuit device, according to various example embodiments;

FIGS. 2 and 3 are cross-sectional views taken along lines I-I′ and II-II′ of FIG. 1; and

FIGS. 4 to 15 are cross-sectional views for describing a method of manufacturing an integrated circuit device, according to various example embodiments.

### DETAILED DESCRIPTION OF VARIOUS EXAMPLE EMBODIMENTS

Hereinafter, some example embodiments will be described in detail with reference to the accompanying drawings. In the drawings, the same elements are denoted by the same reference numerals, and a repeated description thereof will be omitted.

As variously described example embodiments allow for various changes and numerous embodiments, certain example embodiments will be illustrated in the drawings and described in the detailed description. However, this is not intended to limit the scope of the inventive concept to particular modes of practice, and it is to be appreciated that all changes, equivalents, and substitutes that do not depart from the spirit and technical scope of the inventive concept are encompassed in the inventive concept. In the description of the embodiments, certain detailed explanations of the related art are omitted when it is deemed that they may unnecessarily obscure the essence of the inventive concept.

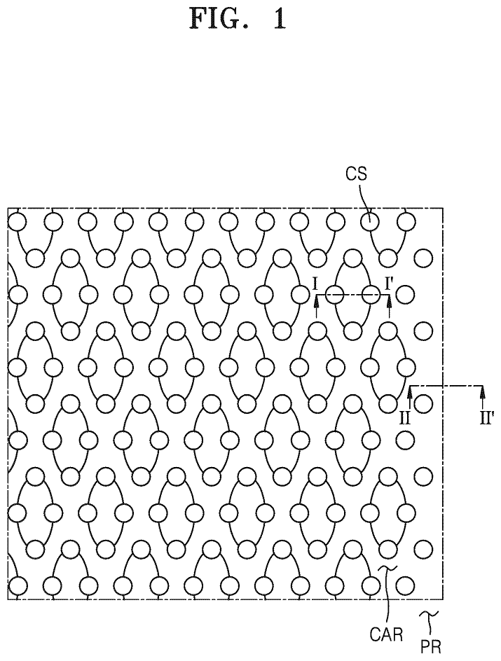

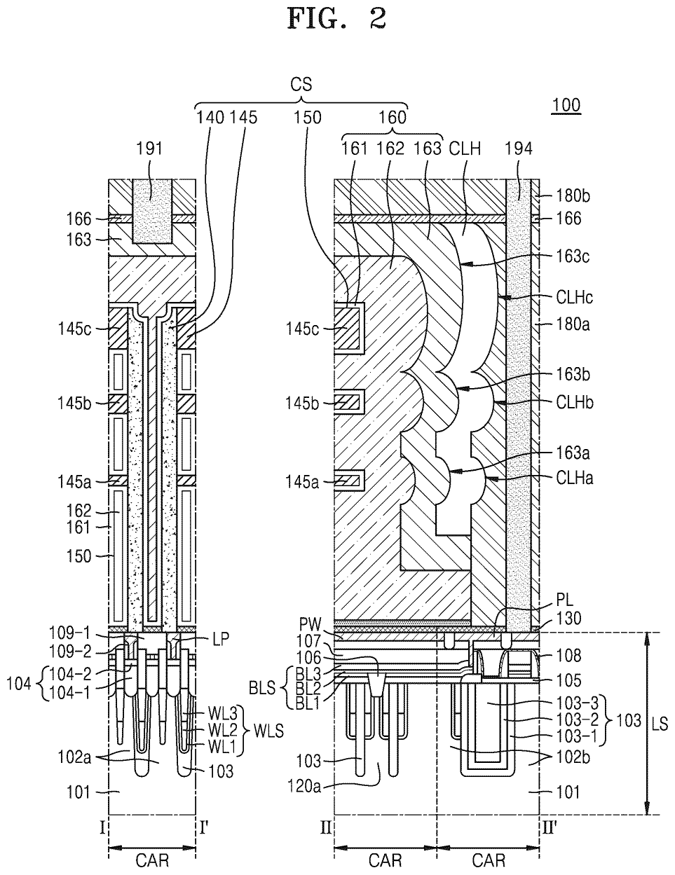

FIG. 1 is a schematic plan view illustrating an integrated circuit device 100, according to inventive concepts. FIG. 2 is a cross-sectional view illustrating the integrated circuit device 100 of FIG. 1 taken along lines I-I′ and II-II′.

Referring to FIGS. 1 and 2, the integrated circuit device 100 may include a lower structure LS, an etch stop layer 130 on the lower structure LS, a memory structure such as a capacitor structure CS including a plurality of lower electrodes 140, a dielectric film 150, and an upper electrode 160, first and second interlayer insulating layers 180a and 180b, and contact plugs (e.g., 191 and 194).

The memory structure such as the capacitor structure CS may be (or include) a capacitor and/or may have some memristor and/or nonlinear characteristics such as hysteresis characteristics; example embodiments are not limited thereto. The arrangement of the capacitor structures CS, when viewed in plan, may be or correspond to points on a lattice, such as a triangular lattice; example embodiments are not limited thereto.

The lower structure LS may include a substrate 101 including active regions 102a, a device isolation region 103 defining the active regions 102a in the substrate 101, a word line structure WLS buried in the substrate 101, extending, and including a word line WL, and a bit line structure BLS located on the substrate 101, extending to cross the word line structure WLS, and including a bit line BL.

The integrated circuit device 100 may be or include or be included in, for example, a cell array of a dynamic random-access memory (DRAM). For example, the bit line BL may be connected to a first impurity region (e.g., a source region) from among the active regions 102, the capacitor structure CS may be electrically connected to a second impurity region (e.g., a drain region) from among the active regions 102a, and data, such as logical ‘1’ or ‘0’, may be stored in the capacitor structure CS.

The substrate 101 may include a cell array area CAR and a peripheral area PR. The capacitor structure CS in which data is stored may be located in the cell array area CAR. Accordingly, the cell array area CAR of the substrate 101 may be defined as a portion of the substrate 101 overlapping the capacitor structure CS in which data is stored. The peripheral area PR may be located around the cell array area CAR. In the peripheral area, one or more of a word line driver, a sense amplifier, row and column decoders, and control circuits may be located.

The substrate 101 may include a semiconductor material, for example, one or more of a group IV semiconductor, a group III-V compound semiconductor or a group II-VI compound semiconductor. The group IV semiconductor may include one or more of silicon, germanium, or silicon germanium. The substrate 101 may further include impurities. The substrate 101 may be, include, or be included in a silicon substrate, a silicon-on-insulator (SOI) substrate, a germanium substrate, a germanium-on-insulator (GOI) substrate, a silicon-germanium substrate, or a substrate including an epitaxial layer.

The active regions 102a may be defined in the substrate 101 by the device isolation region 103. The active region 102a may have a bar shape or a bar shape with extensions in the middle thereof, and may be located in an island shape extending in one direction, for example, a direction toward the word line structure WLS, in the substrate 101. The active regions 102a may be located in the cell array area CAR. In some example embodiments, the integrated circuit device 100 may further include dummy active regions 102b located in the peripheral area PR. The dummy active regions 102b may be defined in the substrate 101 by the device isolation region 103, like the active regions 102a. In some cases, the dummy active regions 102b may not be electrically active during operation of the semiconductor device; example embodiments are not limited thereto.

The device isolation region 103 may be formed by using a shallow trench isolation (STI) process. The device isolation region 103 may surround the active regions 102a and may electrically separate the active regions 102a from each other. The device isolation region 103 may be formed of an insulating material, for example, silicon oxide, silicon nitride, or a combination thereof. In some example embodiments, the device isolation region 103 may be formed with a spin-on dielectric (SOD) process; example embodiments are not limited thereto. The device isolation region 103 may include a plurality of regions having lower depths that vary according to a width of a trench etched in the substrate 101. The device isolation region 103 may include a first device isolation layer defining the active regions 102a in the cell array area CAR and a second device isolation layer defining the dummy active regions 102b in the peripheral area PR. A dummy gate structure may be located on the dummy active regions 102b, but inventive concepts are not limited thereto. In the peripheral area PR, the device isolation region 103 may include a plurality of layers. For example, in an area adjacent to the word line WL as shown in FIG. 2, the device isolation region 103 may include a first insulating liner 103-1, a second insulating liner 103-2, and a buried insulating layer 103-3. The first insulating liner 103-1, the second insulating liner 103-2, and the buried insulating layer 103-3 may be sequentially formed in the trench etched in the substrate 101 where the device isolation region 103 is located. In some example embodiments, the first insulating liner 103-1 and a buried insulating layer 113 may include silicon oxide and may or may not include silicon nitride, and the second insulating liner 103-2 may include silicon nitride and may or may not include silicon oxide.

The word line structure WLS may include a word line WL1, a gate dielectric layer WL2, and a gate capping layer WL3. The word line WL1 may extend in a first direction (X direction) across the active regions 102. For example, one pair of word lines WL1 adjacent to each other may be arranged to cross one active region 102a. A top surface of the word line WL1 may be located at a lower level than a top surface of the substrate 101. As used herein, high and low levels may be defined based on a substantially flat top surface of the substrate 101. Although the word line WL1 may constitute (or be included in) a gate of a buried channel array transistor (BCAT), inventive concepts are not limited thereto. According to various example embodiments, the word line WL1 may be located on the substrate 101. The word line WL1 may include a conductive material, for example, at least one of polycrystalline silicon (Si) such as doped poly, titanium (Ti), titanium nitride (TiN), tantalum (Ta), tantalum nitride (TaN), tungsten (W), tungsten nitride (WN), and aluminum (Al). According to various example embodiments, the word line WL may have a double layer structure formed of different materials.

The gate dielectric layer WL2 may conformally cover a side surface and a bottom surface of the word line WL1. The gate dielectric layer WL2 may include at least one of silicon oxide, silicon nitride, and silicon oxynitride. The gate dielectric layer WL2 may be or include, for example, a silicon oxide film and/or an insulating film having a high dielectric constant (higher than that of silicon oxide).

The gate capping layer WL3 may be located on the word line WL1. The gate capping layer WL3 may be formed of an insulating material, for example, silicon nitride.

The bit line structure BLS may extend in one direction, for example, a Y direction, perpendicular to the word line WL1. The bit line structure BLS may include bit lines (e.g., BL1 and BL2), and bit line capping pattern BL3 on the bit lines (e.g., BL1 and BL2).

The bit lines (e.g., BL1 and BL2) may include a first conductive pattern BL1 and a second conductive pattern BL2 which are sequentially stacked. The first conductive pattern BL1 may include a semiconductor material such as polycrystalline silicon. The first conductive pattern BL1 may directly contact the first impurity region. The second conductive pattern BL2 may include a metal material such as one or more of titanium (Ti), tantalum (Ta), tungsten (W), and aluminum (Al). According to various example embodiments, a separate conductive pattern may be located between the first and second conductive patterns BL1 and BL2, and the conductive pattern may be, for example, a layer obtained by siliciding a part of the first conductive pattern BL1. However, according to various example embodiments, the number and/or the thickness of conductive patterns constituting a bit line may be changed in various ways.

The bit line capping pattern BL3 may be located on the bit lines (e.g., BL1 and BL2). The bit line capping pattern BL3 may include an insulating material, for example, a silicon nitride film. In some example embodiments, the bit line capping pattern BL3 may include a plurality of capping pattern layers and may be formed of different materials. In some example embodiments, the number and/or types of materials of capping patterns constituting the bit line capping pattern BL3 may be changed in various ways according to various example embodiments.

In various example embodiments, the bit line structure BLS may be located on the word line structure WLS, and a buffer insulating layer 105 may be located between the bit line structure BLS and the word line structure WLS.

In various example embodiments, the lower structure LS may further include a bit line contact pattern 106 passing through the first conductive pattern BL1 and contacting the first impurity region of the active regions 102a. A bottom surface of the bit line contact pattern 106 may be located at a higher level than a top surface of the word line WL1. In various example embodiments, the bit line contact pattern 106 may be integrally formed with the first conductive pattern BL1.

In various example embodiments, the lower structure LS may further include a lower electrode contact pattern 104, cell landing pads LP, a dummy pattern PW, and a peripheral landing pad PL.

The lower electrode contact pattern 104 may be connected to a region of the active regions 102a, for example, the second impurity region. The lower electrode contact pattern 104 may be located between the bit lines (e.g., BL1 and BL2) and between the word lines WL1. A bottom surface of the lower electrode contact pattern 104 may be located at a lower level than a top surface of the substrate 101, and may be located at a higher level than a bottom surface of the bit line contact pattern 106. The lower electrode contact pattern 104 may be formed of a conductive material, for example, at least one of polycrystalline silicon (Si) such as doped poly, titanium (Ti), titanium nitride (TiN), tantalum (Ta), tantalum nitride (TaN), tungsten (W), tungsten nitride (WN), and aluminum (Al). In various example embodiments, the lower electrode contact pattern 104 may include a semiconductor layer 104-1 and a metal semiconductor compound layer 104-2 on the semiconductor layer 104-1. The metal semiconductor compound layer 104-2 may be a layer obtained by siliciding a part of the semiconductor layer 104-1, and may include, for example, one or more of cobalt silicide (CoSi), titanium silicide (TiSi), nickel silicide (NiSi), tungsten silicide (WSi), or other metal silicide. According to various example embodiments, the metal semiconductor compound layer 104-2 may be omitted.

The cell landing pad LP, the dummy pattern PW, and the peripheral landing pad PL may be conductive patterns located on the bit line structure BLS and the lower electrode contact pattern 104. The cell landing pad LP, the dummy pattern PW, and the peripheral landing pad PL may be defined when a conductive layer is separated by an insulating pattern 109-1. The cell landing pad LP may be located in the cell array area CAR and may be electrically connected to the lower electrode contact pattern 104. The dummy pattern PW may be located in a dummy area at an edge of the cell array area CAR. The peripheral landing pad PL may be electrically connected to the bit line structure BLS in the peripheral area PR. However, according to various example embodiments, the peripheral landing pad PL may be electrically connected to the word line structure WLS and/or may be connected to other peripheral circuit devices. In various example embodiments, the cell landing pad LP, the dummy pattern PW, and the peripheral landing pad PL may include a barrier layer and a conductive layer. The barrier layer may include metal nitride covering a bottom surface and side surfaces of the conductive layer, for example, at least one of titanium nitride (TiN), tantalum nitride (TaN), and tungsten nitride (WN). The conductive layer may include a conductive material, for example, at least one of polycrystalline silicon (Si) such as doped poly, titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

In various example embodiments, the integrated circuit device 100 may include the insulating pattern 109-1 and an insulating liner 108 passing through the cell landing pad LP, the dummy pattern PW, and the peripheral landing pad PL. The cell landing pad LP may be separated into a plurality of parts by the insulating pattern 109-1. The insulating pattern 109-1 may include an insulating material, for example, at least one of silicon oxide, silicon nitride, and silicon oxynitride. The insulating liner 108 may cover peripheral transistors located in the peripheral area PR and may separate the insulating pattern 109-1 from the peripheral transistors.

The etch stop layer 130 may be located on the lower structure LS. The etch stop layer 130 may extend to the peripheral area PR while covering the lower structure LS in the cell area CAR.

The capacitor structure CS may be located in the cell array area CAR of the lower structure LS. The capacitor structure CS may include the plurality of lower electrodes 140, at least one supporter layer 145, the dielectric film 150, and the upper electrode 160.

The plurality of lower electrodes 140 may include a conductive material, for example, titanium nitride (TiN) or polysilicon doped with impurities. The plurality of lower electrodes 140 may each have a pillar shape or a cylindrical shape. Each of the plurality of lower electrodes 140 may pass through each stop layer 130 and may be electrically connected to the cell landing pad LP.

The supporter layers 145 may be spaced apart from each other in a Z direction perpendicular to a top surface of the lower structure LS and may extend in a horizontal direction perpendicular to the Z direction. The supporter layers 145 may contact the plurality of lower electrodes 140 and may connect side walls of a plurality of adjacent lower electrodes 140. The supporter layers 145 may be a structure supporting (e.g., mechanically supporting) the plurality of lower electrodes 140 having a high aspect ratio. The supporter layers 145 may include at least one of, for example, silicon oxide, silicon nitride, and silicon oxynitride. In various example embodiments, the supporter layers 145 may include a first supporter layer 145a, a second supporter layer 145b on the first supporter layer 145a, and a third supporter layer 145c on the second supporter layer 145b which are sequentially stacked. A composition of the first supporter layer 145a, the second supporter layer 145b, and the third supporter layer 145c may be the same as each other, or may be different from amongst each other. The first supporter layer 145a may have a thickness less than that of the second supporter layer 145b, and the second supporter layer 145b may have a thickness less than that of the third supporter layer 145c. Alternatively or additionally, a distance between the lower structure LS and a bottom surface of the first supporter layer 145a may be greater than a distance between a top surface of the first supporter layer 145a and a bottom surface of the second supporter layer 145b. Alternatively or additionally, a distance between a top surface of the first supporter layer 145a and a bottom surface of the second supporter layer 145b may be greater than a distance between a top surface of the second supporter layer 145b and a bottom surface of the third supporter layer 145c. However, this is only an example, and the composition, the number, thickness, and/or arrangement relationship of supporter layers are not limited thereto and may be changed in various ways.

The dielectric film 150 may be located on the lower structure LS and may cover the plurality of lower electrodes 140 and the supporter layers 145. The dielectric film 150 may conformally cover a top surface and side surfaces of the plurality of lower electrodes 140, a top surface of the etch stop layer 130, and exposed surfaces of the supporter layers. The dielectric film 150 may include a high-k material, or may include silicon oxide, silicon nitride, silicon oxynitride, or a combination thereof. However, according to various example embodiments, the dielectric film 150 may include one or more of oxide, nitride, silicide, oxynitride, or silicide-oxynitride including one of or more than one of hafnium (Hf), aluminum (Al), zirconium (Zr), and lanthanum (La).

The upper electrode 160 may cover the plurality of lower electrodes 140, the supporter layers 145, and the dielectric film 150. The upper electrode 160 may fill a space between the plurality of lower electrodes 140 and a space between the supporter layers 145.

The upper electrode 160 may include a metal-containing film 161, a first material film 162, and a plate layer 163 sequentially formed on the plurality of lower electrodes 140. The metal-containing film 161 may be a conductive layer conformally covering the dielectric film 150. The metal-containing film 161 may be, for example, titanium nitride (TiN). The first material film 162 may fill a space between the plurality of lower electrodes 140 and a space between the supporter layers 145 while covering the metal-containing film 161. The first material film 162 may include a semiconductor material, and for example, silicon germanium (SiGe) including impurities such as at least one of boron, phosphorus, or arsenic. The plate layer 163 may conformally cover a side surface of the first material film 162. In various example embodiments, a thickness of the plate layer 163 may be equal to or less than a thickness of the first material film 162. In various example embodiments, a thickness of the plate layer 163 may be greater than a thickness of the first material film 162. In various example embodiments, the plate layer 163 may include tungsten (W).

The upper electrode 160 may include one or more protruding areas protruding in the horizontal direction from the cell array area CAR to the peripheral area PR. The protruding areas may be located on a side surface of the upper electrode 160. The side surface of the upper electrode 160 may have a portion having a convex shape in the horizontal direction due to the protruding areas. The protruding areas may be formed to cover the supporter layers 145 extending in the horizontal direction from the plurality of lower electrodes 140. Accordingly, the protruding areas may include portions located at substantially the same level as the supporter layers 145.

In various example embodiments, the plate layer 163 may include protruding areas. The protruding areas of the plate layer 163 may include a first protrusion 163a, a second protrusion 163b, and a third protrusion 163c. The first protrusion 163a may be a protrusion including a portion located at substantially the same level as the first supporter layer 145a, the second protrusion 163b may be a protrusion including a portion located at substantially the same level as the second supporter layer 145b, and the third protrusion 163c may be a protrusion including a portion located at substantially the same level as the third supporter layer 145c. Protruding distances of the first to third protrusions 163a, 163b, and 163c may vary according to thicknesses of the first to third supporter layers 145a, 145b, and 145c respectively corresponding to the first to third protrusions 163a, 163b, and 163c. In various example embodiments, at least some of the first to third protrusions 163a, 163b, and 163c may protrude from the cell array area CAR and be located in the peripheral area PR.

The first and second interlayer insulating layers 180a and 180b may be located on the lower structure LS and may cover the capacitor structure CS and the etch stop layer 130. The first and second interlayer insulating layers 180a and 180b may cover a top surface and a side surface of the upper electrode 160. The first and second interlayer insulating layers 180a and 180b may include silicon oxide. According to various example embodiments, the first and second interlayer insulating layers 180a and 180b may be formed of one or more of a plasma enhanced (PE)-tetraethyl orthosilicate (TEOS) film, phosphorous silicate glass (PSG), or high density plasma (HDP) oxide.

The contact plugs (e.g., 191 and 194) may include an upper electrode contact plug 191 electrically connected to the upper electrode 160 and a peripheral contact plug 194 electrically connected to the lower structure LS.

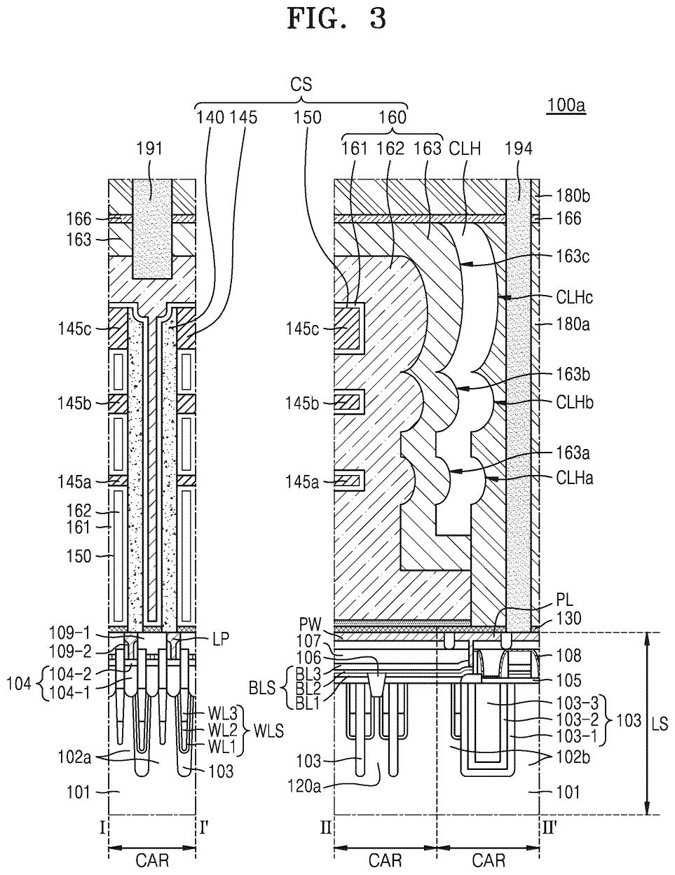

The upper electrode contact plug 191 may pass through the second interlayer insulating layer 180b, the oxide layer 166, and a part of the upper electrode 160 in the cell array area CAR and may be electrically connected to the upper electrode 160. Referring to FIG. 3, the upper electrode contact plug 191 may pass through the plate layer 163 and may extend into the first material film 162 to be connected to the upper electrode 160. However, as shown in FIG. 2, the upper electrode contact plug 191 may pass through only a part of the plate layer 163 and may not contact the first material film 162.

The peripheral contact plug 194 may pass through the second interlayer insulating layer 180b, the oxide layer 166, the first interlayer insulating layer 180a, and the etch stop layer 130 in the peripheral area PR and may be electrically connected to the lower structure LS. In various example embodiments, the peripheral contact plug 194 may contact the peripheral landing pad PL and may be electrically connected to the bit line structure BLS, but inventive concepts are not limited thereto. The peripheral contact plug 194 may include a conductive material that is the same as or similar to that of the upper electrode contact plug 191.

FIG. 3 is a cross-sectional view taken along lines I-I′ and II-II′ of FIG. 1. In FIG. 3, the same members as those in FIG. 2 are denoted by the same reference numerals, and a repeated description thereof will be omitted. An integrated circuit device 100a has only a slight difference in a shape of the upper electrode contact plug 191 compared to the integrated circuit device 100 of FIG. 2, and thus, the following will focus on the difference.

Referring to the integrated circuit device 100a of FIG. 3, the upper electrode contact plug 191 may pass through the plate layer 163 and may contact the first material film 162. In some example embodiments, a bottom surface of the upper electrode contact plug 191 may be located at a lower level in the Z direction than a bottom surface of the plate layer 163. Even when the upper electrode contact plug 191 partially contacts the first material film 162 as shown in FIG. 3, inventive concepts may be applied.

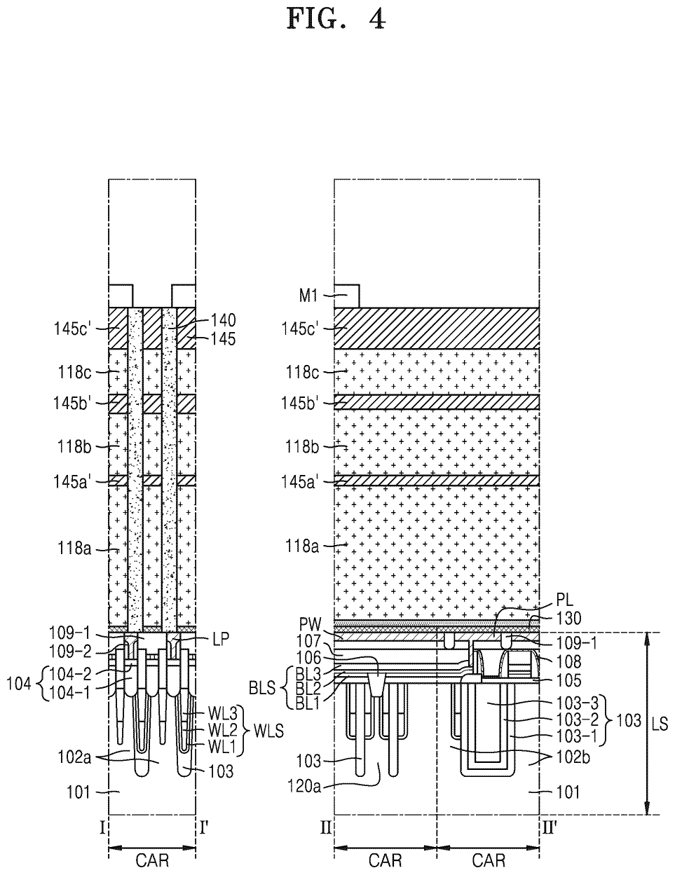

FIGS. 4 to 15 are cross-sectional views for describing a method of manufacturing/fabricating the integrated circuit device 100, according to various example embodiments. In detail, FIGS. 4 to 15 are cross-sectional views illustrating the integrated circuit device 100 of FIGS. 1 and 2 taken along lines I-I′ and II-II′. Hereinafter, a method of manufacturing the integrated circuit device 100 will be described also with reference to FIGS. 1 and 2.

Referring to FIG. 4, the lower structure LS may be formed, e.g., using one or more of a deposition process such as a chemical vapor deposition (CVD) process and/or a sputter deposition process, an etching process such as a wet etching process and/or a dry etching process, a photolithography process, a planarization process such as a chemical mechanical planarization (CMP) process, an annealing process such as a rapid thermal annealing (RTA) process, and/or an ion implantation process such as a beamline ion implantation process. Additionally, mold layers 118 and preliminary supporter layers 145′ may be alternately stacked on the lower structure LS, and the plurality of lower electrodes 140 passing through the mold layers 118 and the preliminary supporter layers 145′ may be formed.

The active regions 102a and the device isolation region 103 defining the active regions 102a may be formed on the substrate 101 including the cell array area CAR and the peripheral area PR. In various example embodiments, the cell array area CAR may be or may include a memory cell array area of a memory device such as a DRAM, and the peripheral area PR may be an area including a peripheral circuit around the memory cell array area. Trenches extending in a first direction may be formed by removing a part of the substrate 101, and the word line structure WLS may be formed in the trenches. Impurity regions may be formed on both sides of the word line structure WLS, and the buffer insulating layer 105 and the bit line structure BLS extending in a second direction intersecting the first direction may be formed on the word line structure WLS. The lower electrode contact pattern 104 may be formed by filling a conductive material in a lower electrode contact hole passing through at least a part of the bit line structure BLS in the cell array area CAR. An opening passing through a part of the bit line structure BLS to expose a part of the bit line structure BLS may be formed, the opening and the bit line structure BLS may be covered with a conductive material, and the cell landing pad LP in the cell array area CAR, the peripheral landing pad PL in the peripheral area PR, and via holes connected to the cell landing pad LP or the peripheral landing pad PL may be formed by forming an insulating pattern 109-1 that separates the conductive material. Accordingly, the lower structure LS including the substrate 101, the bit line structure BLS, and the word line structure WLS may be formed.

Next, the etch stop layer 130 may be conformally formed or deposited on the lower structure LS, and the mold layers 118 and the preliminary supporter layers 145′ may be alternately stacked on the etch stop layer 130. The etch stop layer 130 may include an insulating material having etch selectivity under a specific etching condition with the mold layers 118, for example, at least one of silicon nitride (SiN) and silicon carbonitride (SiCN). In some cases, the etch stop layer 130 may etch slower than the mold layers 118 with respect to the specific etching condition. The etching condition may be a wet etching condition and/or a dry etching condition. In some example embodiments, each of the mold layers 118 and the preliminary supporter layers 145′ may include three layers. The preliminary supporter layers 145′ may include a first preliminary supporter layer 145a′, a second preliminary supporter layer 145b′, and a third preliminary supporter layer 145c′ which are sequentially stacked. The first preliminary supporter layer 145a′ may have a thickness less than that of the second preliminary supporter layer 145b′, and the second preliminary supporter layer 145b′ may have a thickness less than that of the third preliminary supporter layer 145c′. The mold layers 118 may include first to third mold layers 118a, 118b, and 118c which are sequentially stacked. The first mold layer 118a may have a thickness greater than that of the second mold layer 118b, and the second mold layer 118b may have a thickness greater than that of the third mold layer 118c. Each of the mold layers 118 and the preliminary supporter layers 145′ may include a material having etch selectivity under a specific etching condition, e.g., may etch slower under a specific etching condition. For example, the mold layers 118 may include silicon oxide, and the preliminary supporter layers 145′ may include silicon nitride. However, according to various example embodiments, the mold layers 118 may include different materials. For example, the third mold layer 118c may include a nitride-based material, unlike the first and second mold layers 118a and 118b.

Next, a plurality of holes passing through the mold layers 118 and the preliminary supporter layers 145′ in the cell array area CAR may be formed, and the lower electrodes 140 may be formed by filling a conductive material in the plurality of holes. The plurality of holes may be formed with an etching process such as a dry etching process having high anisotropy; however, example embodiments are not limited thereto. The plurality of holes may pass through the etch stop layer 130 to expose the cell landing pad LP. The plurality of lower electrodes 140 may be formed by filling a conductive material in the plurality of holes and performing a chemical mechanical polishing (CMP) process or the like.

Next, a first mask M1 may be formed on the uppermost preliminary supporter layer 145′ in the cell array area CAR. The first mask M1 may have a structure including a plurality of hole-shaped openings through which at least parts of the plurality of lower electrodes 140 are exposed.

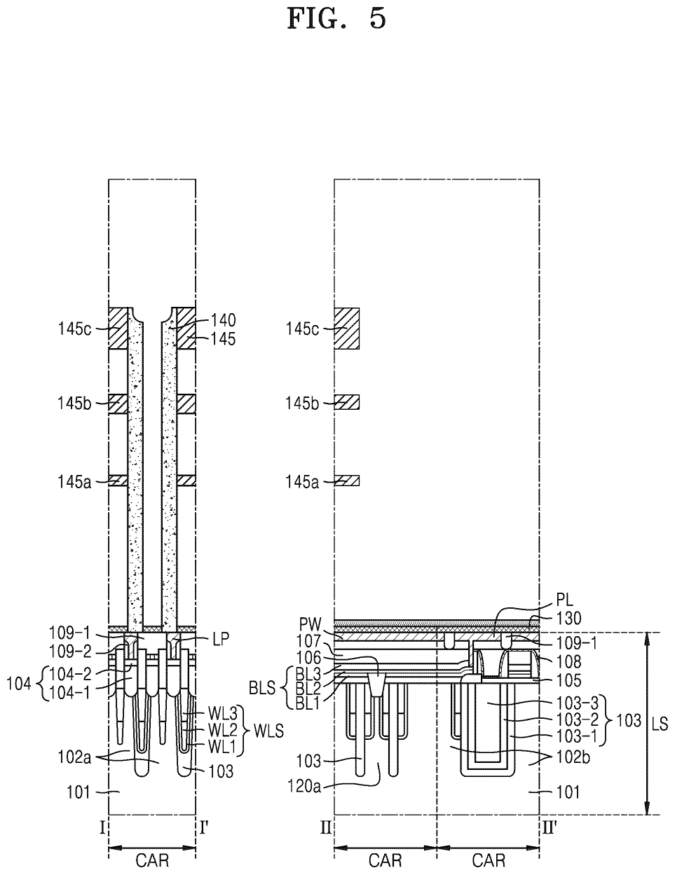

Referring to FIG. 5, the supporter layers 145 may be formed by removing at least parts of the mold layers 118 (see FIG. 4) and the preliminary supporter layers 145′ (see FIG. 4) by using the first mask M1 (see FIG. 4) as an etch mask, and the remaining mold layers 118 (see FIG. 4) may be removed. In some cases, the mold layers 118 may be removed with a wet etching process such as with an etching process having an acid such as buffered hydrogen fluoride (BHF) and/or hot phosphoric acid; however, example embodiments are not limited thereto.

The first mask M1 (see FIG. 4) may be a mask for forming the supporter layers 145. The supporter layers 145 may be formed by performing an etching process on portions of the mold layers 118 (see FIG. 4) and the preliminary supporter layers 145′ (see FIG. 4) not overlapping in the Z direction the first mask M1 by using the first mask M1 as an etch mask.

Each of the supporter layers 145 may be patterned according to a structure of the first mask M1 to have a plurality of openings. At least a portion of the plurality of lower electrodes 140 with an exposed top surface may also be etched during the etching process. The supporter layers 145 may connect a plurality of adjacent lower electrodes 140. The remaining mold layers 118 may be selectively removed with respect to the supporter layers 145.

In various example embodiments, the third supporter layer 145c may be formed by etching the third preliminary supporter layer 145c′ (see FIG. 4) by using an anisotropic etching process such as a dry etching process, and the third mold layer 118c (see FIG. 4) may be removed by using an isotropic etching process such as a wet etching process performed before the second preliminary supporter layer 145b′ (see FIG. 4) is etched. Likewise, the second mold layer 118b may be removed by etching the second preliminary supporter layer 145b′ by using an anisotropic etching process such as a dry etching process, the first supporter layer 145a may be formed by etching the first preliminary supporter layer 145a′ (see FIG. 4) by using an anisotropic etching process such as a wet etching process, and then the first mold layer 118a may be removed by using an isotropic etching process. The first mask M1 may be removed after the mold layers 118 are etched or while the mold layers 118 are etched.

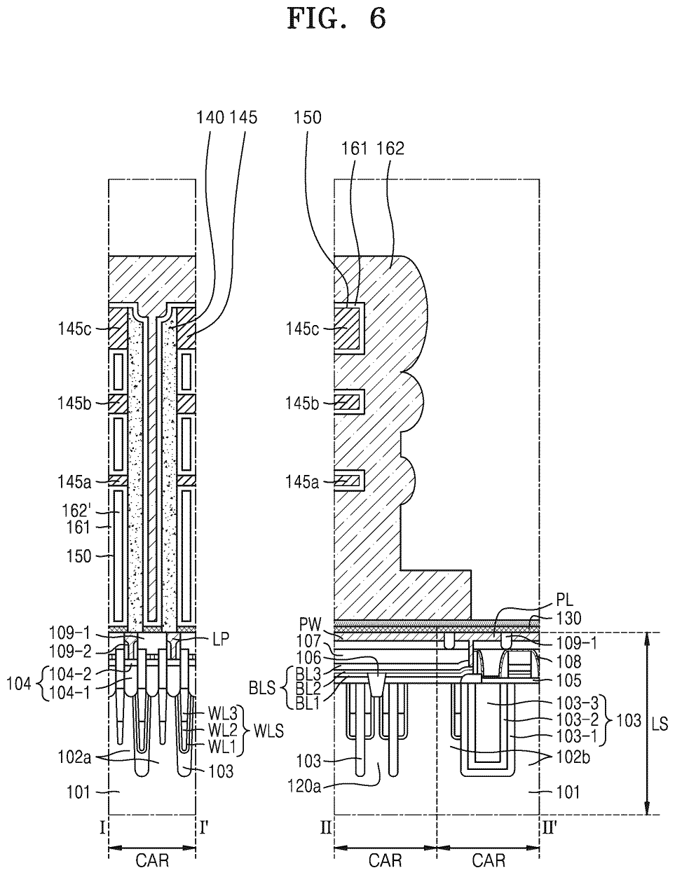

Referring to FIG. 6, the dielectric film 150, the metal-containing film 161, and the first material film 162 covering the plurality of lower electrodes 140 and the supporter layers 145 connected to the plurality of lower electrodes 140 may be sequentially formed.

The dielectric film 150 conformally covering exposed surfaces of the lower electrodes 140 and surfaces of the supporter layers 145 together with the etch stop layer 130 may be formed, e.g., with a process such as a CVD process such as a plasma enhanced CVD (PECVD) and/or a low pressure CVD (LPCVD) and/or an atomic layer deposition (ALD) process. The dielectric film 150 may include a high-k dielectric, silicon oxide, silicon nitride, silicon oxynitride, or a combination thereof. The metal-containing film 161 may include, for example, titanium nitride (TiN). The first material film 162 may cover the plurality of lower electrodes 140 and the supporter layers 145 while filling between the plurality of lower electrodes 140 on the dielectric film 150. The first material film 162 may be formed, e.g., with a CVD process and/or an ALD process, to cover the etch stop layer 130 while extending from the cell array area CAR to the peripheral area PR, and then may be obtained using etching to a certain thickness through a photoresist mask (not shown). The first material film 162 may include a semiconductor material, for example, silicon germanium (SiGe); however, example embodiments are not limited thereto.

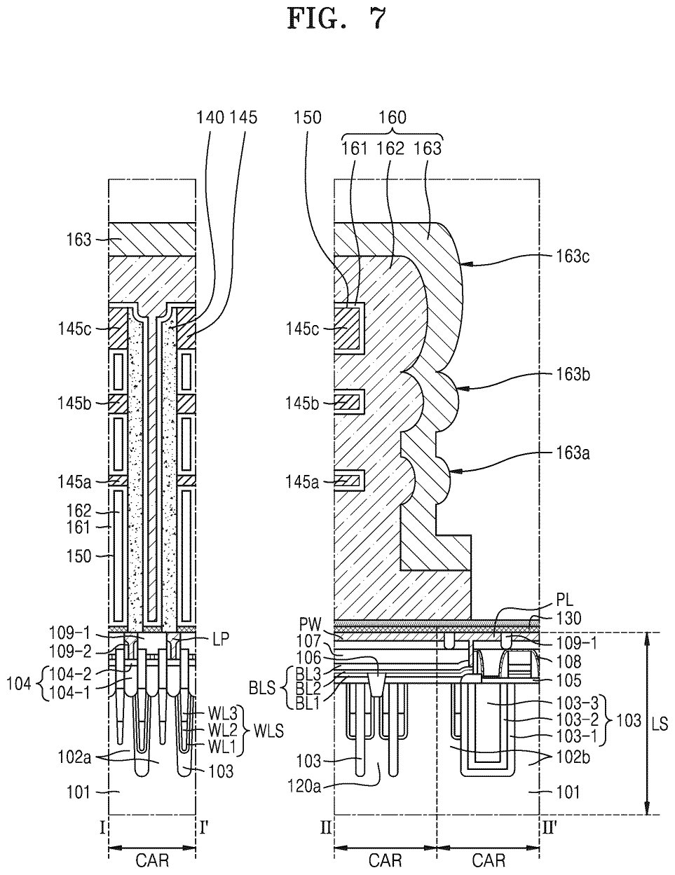

Referring to FIG. 7, in a result of FIG. 6, a preliminary plate layer extending from the cell array area CAR to the peripheral area PR while covering a top surface and a side surface of the first material film 162 with a certain thickness may be formed, e.g., with a CVD process and/or an ALD process, and the plate layer 163 may be formed by etching the preliminary plate layer to a certain thickness by using a photoresist mask (not shown). The plate layer 163 may include, for example, tungsten (W).

The first material film 162 and the plate layer 163 may include an area protruding from the supporter layers 145 as the first material film 162 and the plate layer 163 are formed while covering the supporter layers 145 extending from the lower electrodes 140. In various example embodiments, the plate layer 163 may include one or more protruding areas protruding from the cell array area CAR to the peripheral area PR. The protruding areas may be located on an outer surface of the plate layer 163.

In various example embodiments, the protruding areas may include the first protruding area 163a including a portion located at substantially the same level as the first supporter layer 145a, the second protruding area 163b including a portion located at substantially the same level as the second supporter layer 145b, and the third protruding area 163c including a portion located at substantially the same level as the third supporter layer 145c. Sizes and protruding distances of the first to third protrusions 163a, 163b, and 163c may vary according to thicknesses of the supporter layers 145.

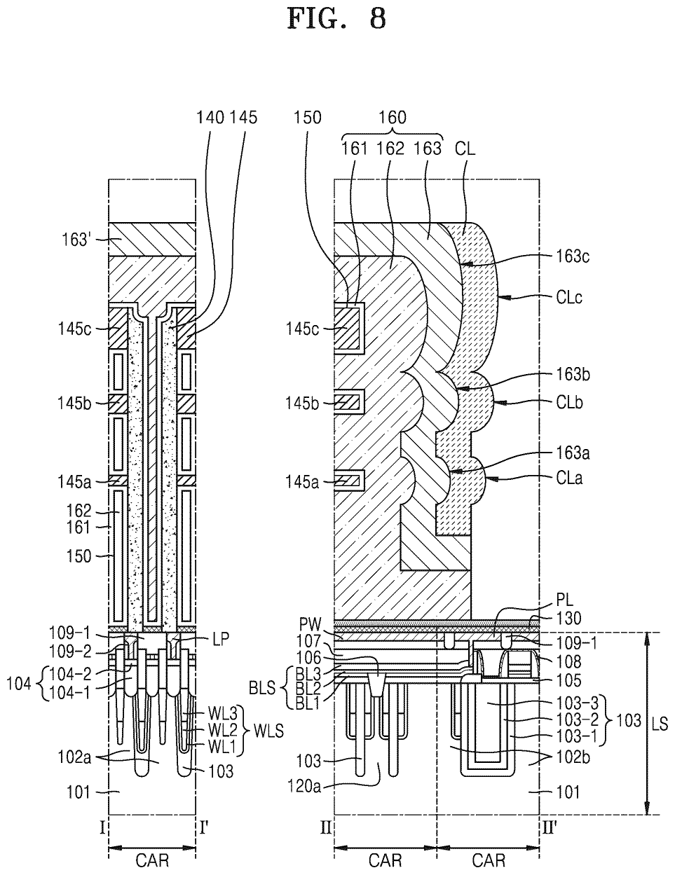

Referring to FIG. 8, a preliminary carbon liner layer extending from the cell array area CAR to the peripheral area PR while covering a top surface and a side surface of the plate layer 163 may be formed, e.g., with a CVD process and/or an ALD process, and a carbon liner layer CL may be obtained by etching (e.g., blanket etching) a top surface of the preliminary carbon linear layer until the top surface of the plate layer 163 and the top surface of the preliminary carbon linear layer are coplanar with each other. The carbon linear layer CL may include pure carbon (C). Alternatively or additionally, in some example embodiments, the carbon layer CL may be planarized with a CMP process; example embodiments are not limited thereto. In various example embodiments, a thickness to which the carbon liner layer CL is deposited may be, but is not limited to, 300 Å to 500 Å. Although a thickness to which the carbon liner layer CL is deposited and a thickness to which the plate layer 163 is deposited are almost the same in FIG. 8, this is only an example and inventive concepts are not limited by a relationship between a thickness of the plate layer 163 and a thickness of the carbon liner layer CL. In some cases, a thickness of the carbon liner layer CL surrounding a side surface of the plate layer 163 may be the same as or different from a thickness of the plate layer 163 surrounding a side surface of the first material film 162.

In various example embodiments, the carbon liner layer CL may include one or more protruding areas protruding in the horizontal direction from the cell array area CAR to the peripheral area PR. The protruding areas may be located on an outer surface of the carbon linear layer CL.

In various example embodiments, the protruding areas may include a first protruding area CLa including a portion located at substantially the same level as the first supporter layer 145a, a second protruding area CLb including a portion located at substantially the same level as the second supporter layer 145b, and a third protruding area CLc including a portion located at substantially the same level as the third supporter layer 145c. Sizes and/or protruding distances of the first to third protrusions CLa, CLb, and CLc may vary, for example, according to thicknesses of the supporter layers 145.

A second mask M2 covering a side surface including protruding areas and a top surface of the carbon liner layer CL covering the plurality of lower electrodes 140 in the cell array area CAR may be formed. The second mask M2 may be an etch mask for separating the capacitor structure CS (see FIG. 2) from structures in the peripheral area PR. A part of a preliminary material film 162′ and a part of a preliminary plate layer 163′ in the peripheral area PR may be removed by using the second mask M2 as an etch mask. Accordingly, the etch stop layer 130 in the peripheral area PR may be exposed.

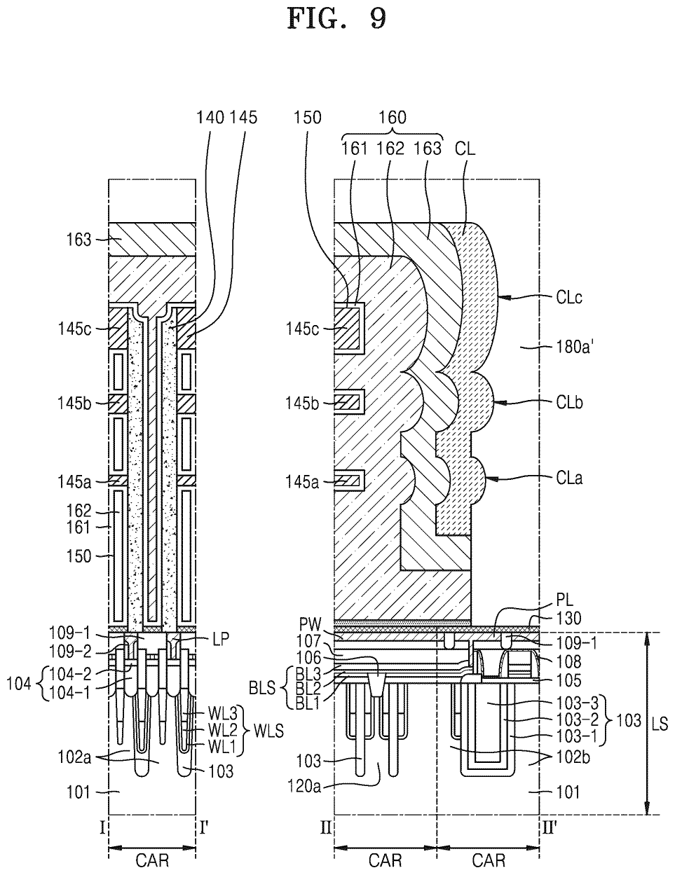

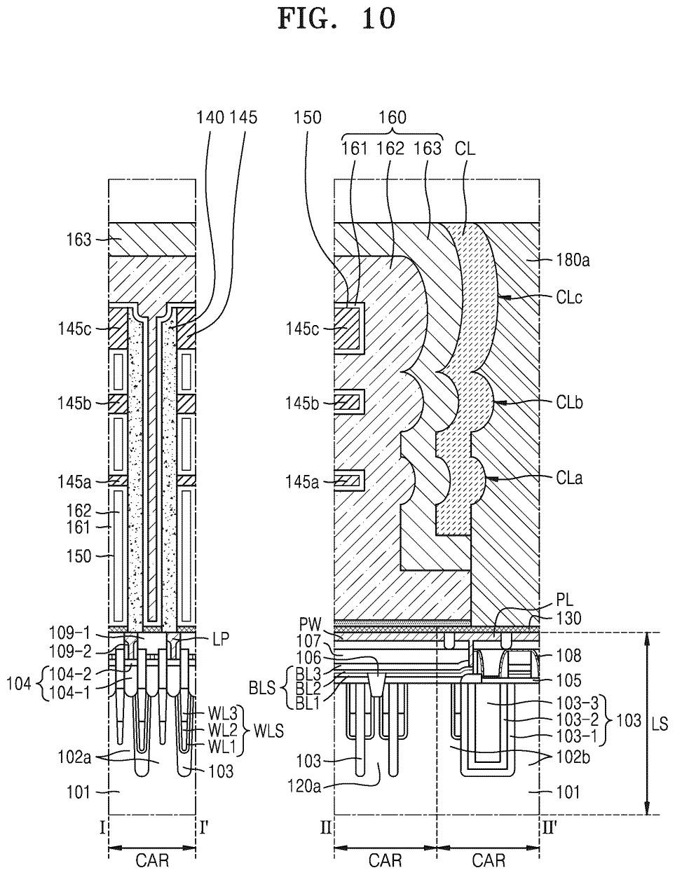

Referring to FIGS. 9 and 10, a preliminary interlayer insulator covering the capacitor structure CS (see FIG. 2) and the etch stop layer 130 in the peripheral area PR may be formed, and a preliminary first interlayer insulating layer 180a′ may be obtained by etching a top surface of the preliminary first interlayer insulator until top surfaces of the upper electrode 160 and the carbon liner layer CL and a top surface of the preliminary first interlayer insulator are coplanar with each other. The preliminary first interlayer insulating layer 180a′ may include an insulating material, for example, TEOS.

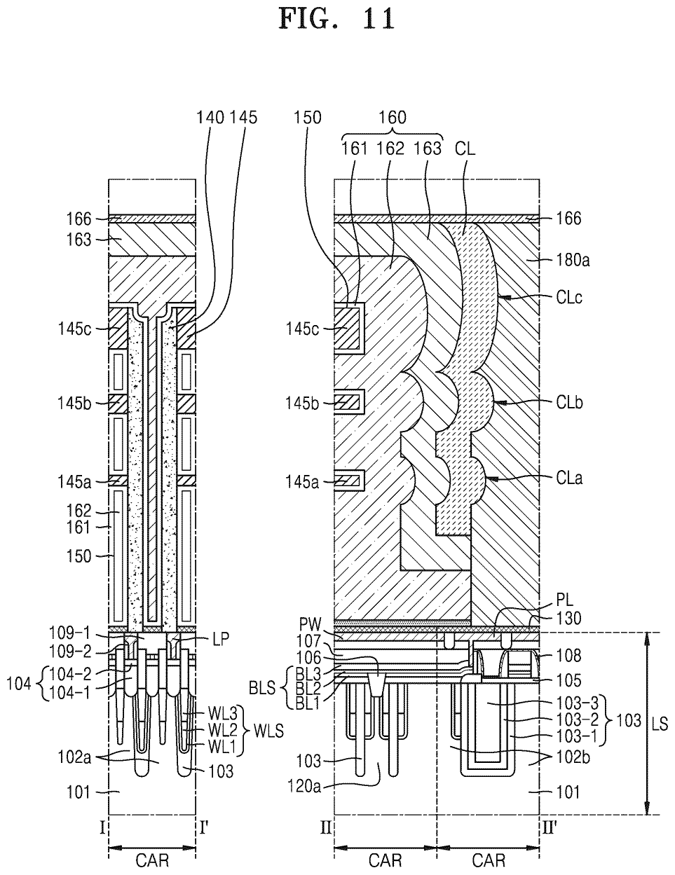

Referring to FIG. 11, the oxide layer 166 conformally covering top surfaces of the upper electrode 160, the carbon liner layer CL, and the preliminary first interlayer insulator 180a′ may be formed. In various example embodiments, the oxide layer 166 may be formed to a thickness of about 10 Å to about 60 Å. For example, the oxide layer 166 may be formed to a thickness of 50 Å. However, inventive concepts are not limited by a thickness of the oxide layer 166.

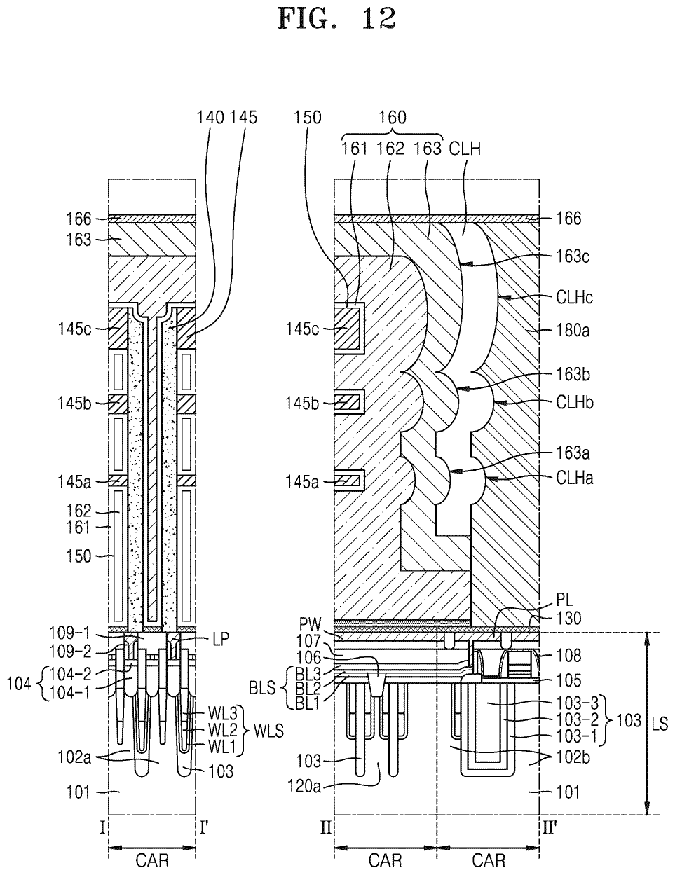

Referring to FIG. 12, carbon © filling the carbon liner layer CL may be removed to form a hole as an air gap CLH. In various example embodiments, the carbon may be selectively removed by a strip process.

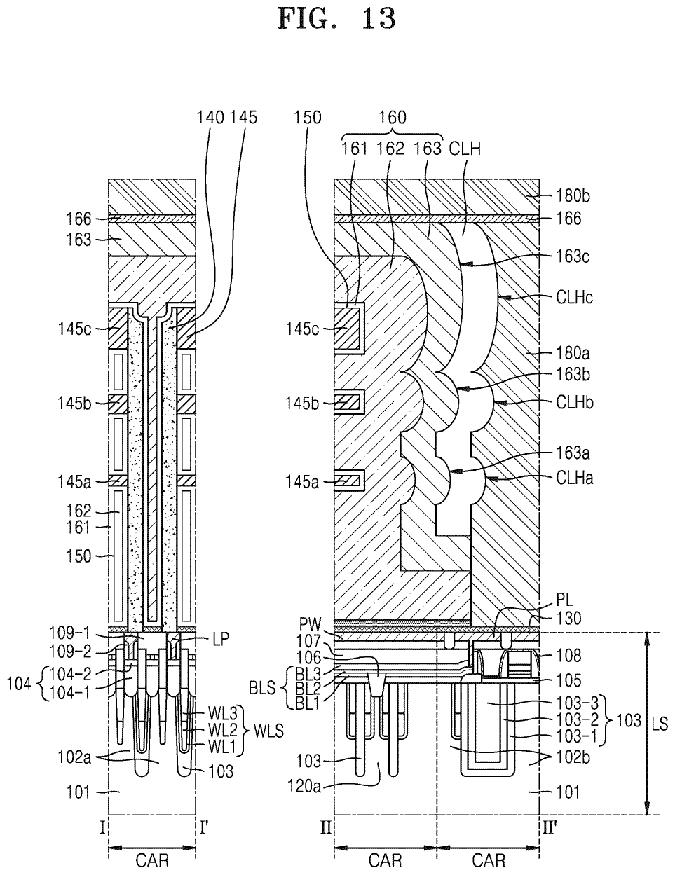

Referring to FIG. 13, the second interlayer insulating layer 180b covering a top surface of the oxide layer 166 may be formed. In various example embodiments, the second interlayer insulating layer 180b may include TEOS. In various example embodiments, the second interlayer insulating layer 180b may have the same composition as the first interlayer insulating layer 180a.

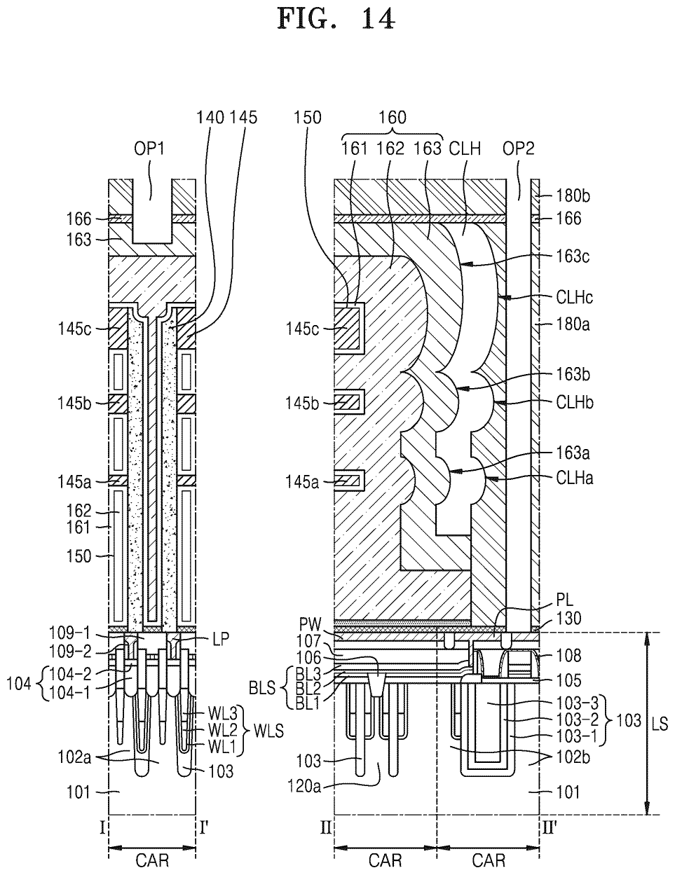

Referring to FIG. 14, a first opening OP1 passing through at least a part of the upper electrode 160 and a second opening OP2 passing through at least a part of the etch stop layer 130 of the peripheral area PR may be formed.

The first opening OP1 may pass through the second interlayer insulating layer 180b, the oxide layer 166, and at least a part of the upper electrode 160 in the cell array area CAR to expose at least a part of the plate layer 163. However, according to various example embodiments, the first opening OP1 may pass through only at least a part of the plate layer 163 and may not extend into the first material film 162 (see FIG. 2). However, inventive concepts are not limited thereto, and the first opening OP1 may extend until the first opening OP1 passes through the plate layer 163 and exposes at least a part of the first material film 162 (see FIG. 3). The first opening OP1 may be a portion where the upper electrode contact plug 191 (see FIG. 2) is formed through a subsequent process.

The second opening OP2 may pass through the second interlayer insulating layer 180b, the oxide layer 166, the first interlayer insulating layer 180a, and at least a part of the etch stop layer 130 in the peripheral area PR. The second opening OP2 may be a portion where the peripheral contact plug 194 (see FIG. 4) is formed through a subsequent process.

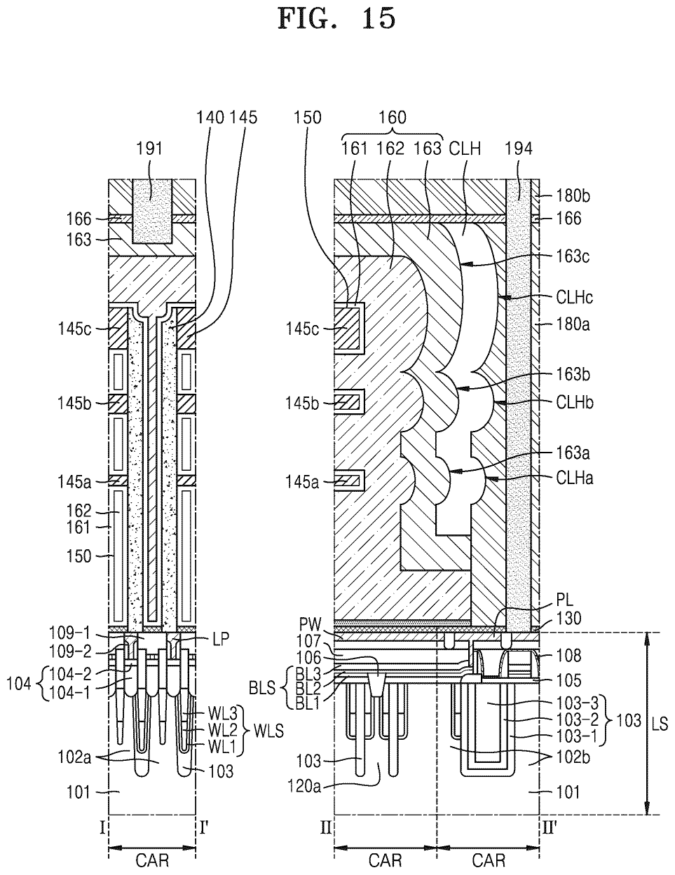

Next, referring to FIG. 15, the upper electrode contact plug 191 may be formed by filling a conductive material in the first opening OP1, and the peripheral contact plug 194 may be formed by filling a conductive material in the second opening OP2. Accordingly, the integrated circuit device 100 (see FIG. 2) with improved electrical reliability by including an air gap on a side surface of a capacitor structure may be provided.

As described above, various example embodiments have been illustrated in the drawings and described in the specification. While some example embodiments have been described using specific terms, this is only used for the purpose of explaining the technical idea of inventive concepts and is not used to limit the meaning and scope of inventive concepts described in the claims. Hence, it will be understood by one of ordinary skill in the art that various modifications and other equivalent embodiments may be made therefrom. Accordingly, the technical scope of inventive concepts should be defined by the following claims.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While inventive concepts have been particularly shown and described with reference to various example embodiments thereof, it will be understood that various changes in form and details may be made therein without departing from the spirit and scope of the following claims. Additionally, example embodiments are not necessarily mutually exclusive with one another. For example, some example embodiments may include one or more features described with reference to one or more figures, and may also include one or more other features described with reference to one or more other figures.

What is claimed is:

1. An integrated circuit device comprising:
a substrate comprising a cell array area and a peripheral area;
a plurality of lower electrodes in the cell array area;
at least one supporter layer contacting the plurality of lower electrodes and extending in a first direction parallel to a top surface of the substrate;
a dielectric film covering the plurality of lower electrodes and the at least one supporter layer;
an upper electrode covering the dielectric film;
a plate layer surrounding a top surface and a side surface of the upper electrode;
an oxide layer contacting a top surface of the plate layer and extending in a second direction parallel to the substrate;
an interlayer insulating layer covering a top surface of the oxide layer and the side surface of the upper electrode; and
a peripheral contact plug passing through the interlayer insulating layer and in the peripheral area of the substrate, wherein
the upper electrode comprises at least one protruding areas protruding in a lateral direction,
the lateral direction is a horizontal direction from the cell array area toward the peripheral area,
the integrated circuit device defines an air gap conformally surrounding the at least one protruding area of the upper electrode in the lateral direction.

2. The integrated circuit device of claim 1, wherein the upper electrode comprises silicon germanium (SiGe), and the plate layer comprises tungsten (W).

3. The integrated circuit device of claim 1, wherein the oxide layer has a thickness of 10 Å to 60 Å.

4. The integrated circuit device of claim 1, further comprising:
an upper electrode contact plug passing through the oxide layer and a part of the upper electrode, and the upper electrode contact plug electrically connected to the upper electrode,
wherein a bottom surface of the upper electrode contact plug contacts the plate layer.

5. The integrated circuit device of claim 1, further comprising:
an upper electrode contact plug passing through the oxide layer and a part of the upper electrode, and the upper electrode contact plug electrically connected to the upper electrode,
wherein the upper electrode contact plug passes through the plate layer.

6. The integrated circuit device of claim 1, wherein the interlayer insulating layer comprises tetraethyl orthosilicate (TEOS).

7. The integrated circuit device of claim 1, wherein
a side surface of the plate layer is physically spaced apart from the interlayer insulating layer by the air gap, and
the top surface of the plate layer contacts the oxide layer.

8. The integrated circuit device of claim 1, wherein a thickness of the air gap in the lateral direction is 300 Å to 500 Å.

9. The integrated circuit device of claim 1, wherein the peripheral contact plug is physically spaced apart from the air gap.

10. An integrated circuit device comprising:
a substrate comprising a cell array area and a peripheral area;
a capacitor structure comprising a plurality of lower electrodes in the cell array area, a dielectric film on the plurality of lower electrodes, and an upper electrode covering the dielectric film;
a plate layer covering a side surface and a top surface of the capacitor structure; and
an interlayer insulating layer covering a top surface and a side surface of the plate layer,
wherein the integrated circuit device further defines an air gap located between the side surface of the plate layer and the interlayer insulating layer.

11. The integrated circuit device of claim 10, wherein
the upper electrode comprises silicon germanium,
the plate layer comprises tungsten, and
the interlayer insulating layer comprises tetraethyl orthosilicate (TEOS).

12. The integrated circuit device of claim 10, wherein the air gap causes at least a part of the side surface of the plate layer to be physically spaced apart from the interlayer insulating layer.

13. The integrated circuit device of claim 10, further comprising:
an upper electrode contact plug passing through a part of the upper electrode to be electrically connected to the upper electrode; and
a peripheral contact plug passing through the interlayer insulating layer located in the peripheral area of the substrate.

14. The integrated circuit device of claim 13, wherein a bottom surface of the upper electrode contact plug passes through a part of the plate layer.

15. The integrated circuit device of claim 13, wherein a bottom surface of the upper electrode contact plug is at a level lower than a bottom surface of the plate layer.

16. The integrated circuit device of claim 13, wherein the peripheral contact plug is physically spaced apart from the air gap.

17. An integrated circuit device comprising:
a substrate comprising a memory cell area and a peripheral circuit area around the memory cell area;
a plurality of cell transistors in the memory cell area;
a peripheral circuit transistor in the peripheral circuit area;
a capacitor structure comprising lower electrodes on the plurality of cell transistors, a dielectric film located on surfaces of the lower electrodes, and an upper electrode located on the dielectric film;
a plate structure covering the capacitor structure;
an oxide layer contacting a top surface of the plate structure and conformally extending in a direction parallel to the substrate;
a first interlayer insulating film between the peripheral circuit transistor in the peripheral circuit area and the oxide layer and the plate structure in the memory cell area;
a second interlayer insulating film on the oxide layer and covering the oxide layer;
an upper electrode contact plug passing through a part of the upper electrode in the memory cell area and electrically connected to the upper electrode; and
a peripheral contact plug sequentially passing through the second interlayer insulating film, the oxide layer, and the first interlayer insulating film in the peripheral circuit area
wherein the integrated circuit device defines an air gap between the first interlayer insulating film and the plate structure and conformally extending on a side surface of the plate structure.

18. The integrated circuit device of claim 17, wherein
each of the first and second interlayer insulating films comprises tetraethyl orthosilicate (TEOS),
the upper electrode comprises silicon germanium, and
the plate structure comprises tungsten.

19. The integrated circuit device of claim 17, wherein
the oxide layer has a thickness of 10 Å to 60 Å, and
the air gap has a thickness of 300 Å to 500 Å.

20. The integrated circuit device of claim 17, wherein a bottom surface of the oxide layer is at a same level as the top surface of the plate structure and an uppermost end of the air gap.
